(19) United States
(12) Patent Application Publication
(10) Pub. No.: US 2007/0246740 A1
(43) Pub. Date: Oct. 25, 2007

(54) TRANSISTOR WITH INCREASED ESD ROBUSTNESS AND RELATED LAYOUT METHOD THEREOF

(76) Inventors: Jing-Chi Yu, Miao- Li Hsien (TW); Yu-Ju Yang, Hsin-Chu City (TW); Chih-His Chen, Hsin-Chu Hsien (TW); Chi-Mo Huang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/380,005

(22) Filed: Apr. 25, 2006

(51) Int. Cl. H01L 29/74

(52) U.S. Cl. 257/173

(57) ABSTRACT

The invention relates to a layout method for a transistor with improved ESD robustness. The layout method includes defining a ring region from a first conductive type; defining a first and a second rectangular diffusion regions from a second conductive type, wherein the first and second rectangular diffusion regions are isolated from each other; defining a ring diffusion region of the second conductive type between the first and second rectangular diffusion regions; defining a first gate electrode between the first rectangular diffusion region of the second conductive type and the ring diffusion region of the second conductive region; and defining a second gate electrode between the second rectangular diffusion region of the second conductive type and the ring diffusion region of the second conductive type.

### BACKGROUND OF THE INVENTION

1. Field of the Invention

The present invention provides a layout method for a transistor. More particularly, to a layout method for transistor that provides increased ESD robustness.

2. Description of the Prior Art

As sizes of transistors continue to grow smaller, the junction between the source and the drain of a transistor (for polar-junction type transistors) becomes more shallow, while the thicknesses of gate oxide layers also becomes thinner. When the thickness of a gate oxide layer becomes thinner, and the breakdown voltage of a bipolar junction transistor reduces, a transistor can easily be damaged by electrostatic discharge (ESD). Therefore, according to the related art, each pin of a chip is protected by an ESD protection element before being coupled to internal circuitry of the chip.

Please refer to FIG. 1. FIG. 1 is a schematic diagram of a prior art protection element 4. One end of the protection element 4 is coupled to a pad 2, while the other end is coupled to a logic circuit 6. If a huge number of electrostatic charges is inputted into the pad 2, transistors MN and MP are turned on to redirect the electric current originated from these electrostatic charges into the VDD and VSS voltage level lines, allowing the operation of logic circuit 6 to remain uninfluenced. However, the ability for transistors MN and MP to redirect the electric current from the source into the drain without damaging themselves depends greatly on the layout of the each transistor.

Please refer to FIG. 2. FIG. 2 is a schematic layout diagram of a prior art NSCR transistor 10. As illustrated by the diagram, a plurality of pads are formed on the NSCR transistor 10, wherein NMOS transistors 8A and 8B are made from regions 24, 22, 18 and regions 26, 20, 16 respectively as illustrated in FIG. 2. A ring region 14 comprises a P type diffusion region, with the plurality of pads from the ring region 14 and N type diffusion regions 16, 18 being coupled to the sources of the NMOS transistors 8A, 8B. A plurality of pads from the N type diffusion regions 24, 26 and the P type diffusion region 12 are coupled to the drains of NMOS transistors 8A, 8B. Poly-silicon regions 20, 22 are coupled to the gates of NMOS transistors 8A, 8B. Please note that the distance between the ring region 14 and the P type diffusion region 12 cannot be too small according to the layout of this transistor; otherwise, a large electric current flowing through the drain will be outputted from the P type diffusion region 12 into the ring region 14 of the parasitic bipolar transistor (the path of the electric current is illustrated with the vertically placed arrow). Therefore, the ability to redirect electrostatic charge in this example is worse than a silicon-controlled rectifier cell (SCR cell) made from a P type diffusion region 12 and N type diffusion regions 16, 18. Mainly for this reason, the above layout method isn't suited for manufacturing of small area transistors.

Please refer to FIG. 3. FIG. 3 is a schematic layout diagram of another prior art NSCR transistor 50. As shown in the diagram, a plurality of pads are formed on the NSCR transistor 50, wherein a NMOS transistor 51 is made form regions 54, 56 and 58 as illustrated in FIG. 3. Ring region 52 is a P type diffusion area, with the plurality of pads of the ring region 52 and the N type diffusion region 54 being coupled to a source of the NMOS transistor 51. Similarly, the plurality of pads of the N type diffusion region 58 and the P type diffusion region 60 are coupled to a drain of the NMOS transistor 51. The poly-silicon region 56 is coupled to a gate of the NMOS transistor 51. Please note that the distance between the source and drain of the NMOS transistor 51 in this transistor layout is spaced even farther to solve the above-mentioned problem regarding large currents in the NSCR transistor 10. However, an excess electric current flowing through the drain will mainly be directed through the P type diffusion region 60. If the area of the P type diffusion region 60 is too small, it may still cause potential NSCR transistor 50 damage.

### SUMMARY OF THE INVENTION

Therefore, the present invention provides a transistor with improved ESD robustness and a related layout method thereof to solve the above-mentioned problems.

According to an embodiment of the claimed invention, a layout method for a transistor with increased ESD robustness is provided. It comprises defining a ring region from a first conductive type on a semiconductor substrate of the first conductive type; defining a first rectangular diffusion region from a second conductive type within one side of the ring region of a first conductive type; defining a second rectangular diffusion region of the second conductive type within another side of the ring region of a first conductive type, with the first and second rectangular diffusion regions of the second conductive type being isolated from each other; defining a ring diffusion region of the second conductive type between the first and second rectangular diffusion regions of the second conductive type; defining a first diffusion region of the first conductive type within an inner side of the ring diffusion region of the second conductive type; defining a first gate electrode between the first rectangular diffusion region of the second conductive type and the ring diffusion region of the second conductive region; and defining a second gate electrode between the second rectangular diffusion region of the second conductive type and the ring diffusion region of the second conductive type. The ring diffusion region of the second conductive type and the diffusion region of the first conductive region correspond to a drain of the transistor, while the first and second rectangular diffusion regions of the second conductive type and the ring region of the first conductive type correspond to a source of the transistor.

According to an embodiment of the claimed invention, a transistor with increased ESD robustness is provided. It comprises a semiconductor substrate from a first conductive type; a ring region of the first conductive type formed on the semiconductor substrate of the first conductive type; a first rectangular diffusion region from a second conductive type formed within one side of the ring region of the first conductive type; a second rectangular diffusion region of a second conductive type formed within another side of the ring region of the first conductive type, and the first and second rectangular diffusion regions of the second conductive type being isolated from each other; a ring diffusion region of the second conductive type formed between the first and second rectangular diffusion regions of the second conductive type; a first diffusion region of the first conductive type formed within an inner side of the ring diffusion region of the second conductive type; a first gate electrode formed between the first rectangular diffusion region of the second conductive type and the ring diffusion region of the second conductive region; and a second gate electrode formed between the second rectangular diffusion region of the second conductive type and the ring diffusion region of the second conductive type. The ring diffusion region of the second conductive type and the diffusion region of the first conductive region correspond to a drain of the transistor, while the first and second rectangular diffusion regions of the second conductive type and the ring region of the first conductive type correspond to a source of the transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a prior art protection element.

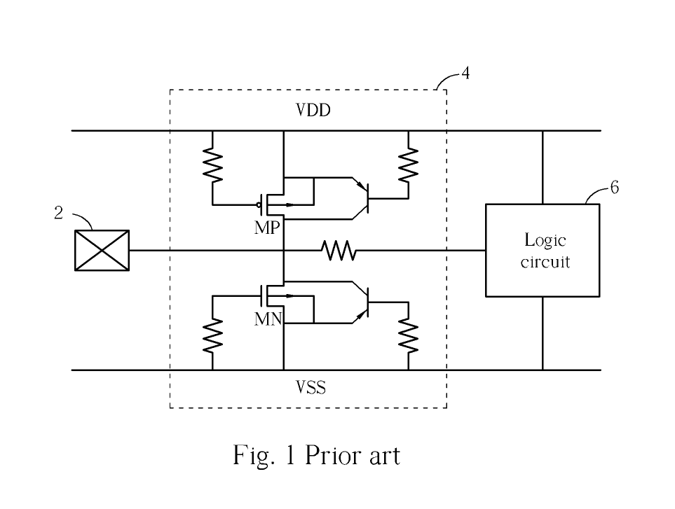

FIG. 2 is a schematic layout diagram of a prior art NSCR transistor.

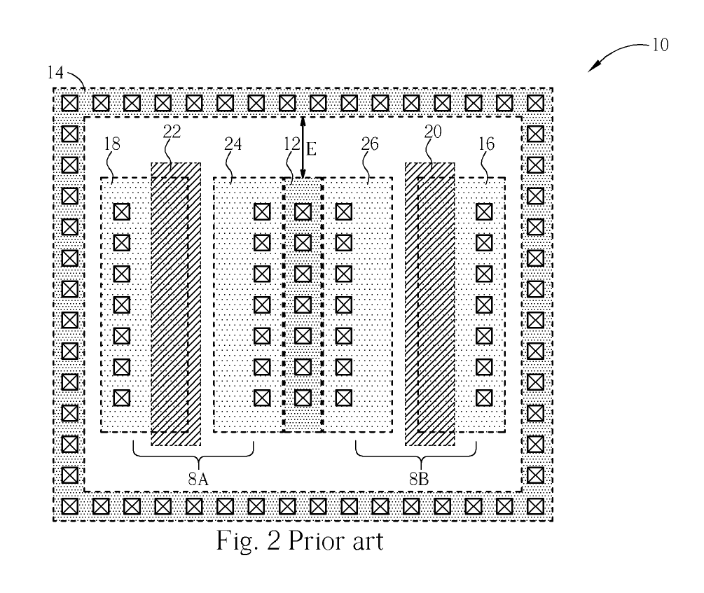

FIG. 3 is a schematic layout diagram of another prior art NSCR transistor.

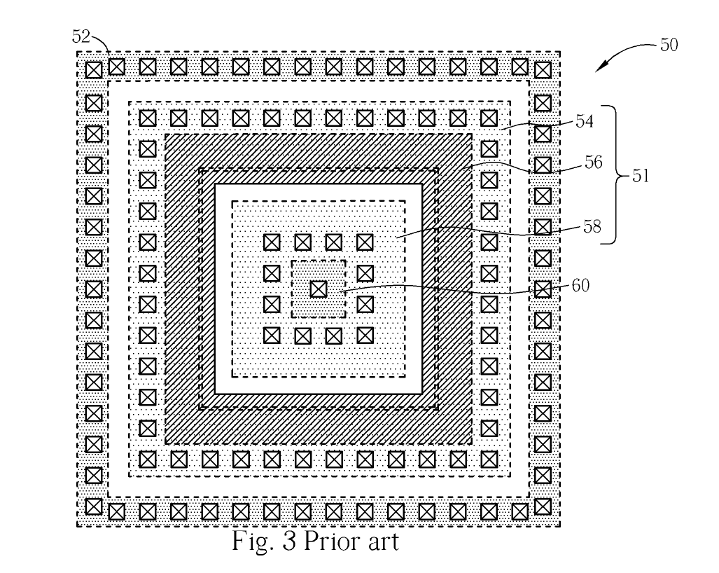

FIG. 4 is a schematic layout diagram of an NSCR transistor according to an embodiment of the present invention.

FIG. 5 is a cross-section view of the NSCR transistor shown in FIG. 4.

### DETAILED DESCRIPTION

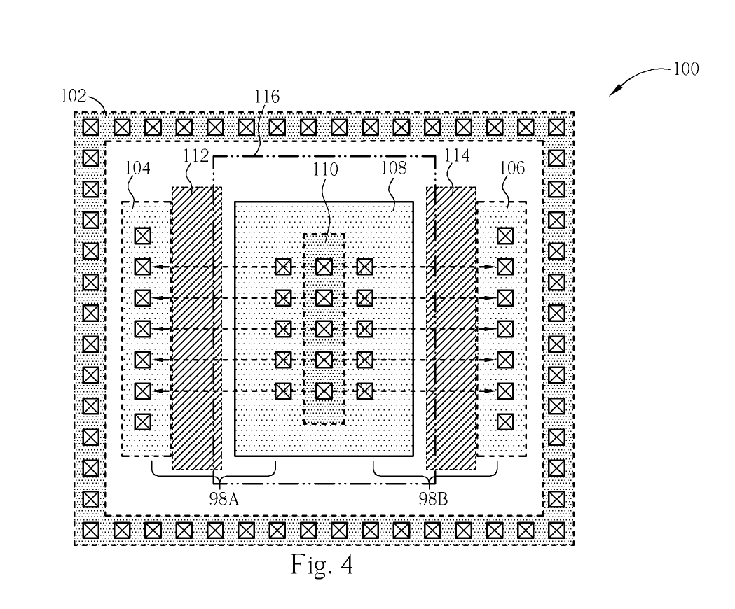

Please refer to FIG. 4. FIG. 4 is a schematic layout diagram of an NSCR transistor 100 according to an embodiment of the present invention. In this embodiment, the NSCR transistor 100 is a silicon-controlled rectifier cell (SCR cell), which includes NMOS transistors 98A, 98B made from regions 108, 112, 114, 104, and 106, a P type semiconductor substrate (not shown), a P type ring region 102, two rectangular N type diffusion regions 104, 106, an N type ring diffusion region 108, a P type diffusion region 110, and poly-silicon regions 112, 114. The area enclosed by the dotted line 116 includes an N type well being surrounded under an N type ring diffusion 108, P type diffusion region 110, and portions of poly-silicon regions 112, 114. As shown through FIG. 4, the pads of the rectangular N type diffusion region 104, 106, and the P type ring region 102, are coupled to the source of the NSCR transistor 100. The pads of the ring N type diffusion region 108 and the P type diffusion region 110 are coupled to the drain of NSCR transistor 100. The pads of poly-silicon regions 112, 114 are coupled to the gate of the NSCR transistor 100. Because the P type diffusion region 110 is rectangular, and the cross-sectional area of the P type diffusion region 100 parallel to the source 104 is larger, if damage from an electrostatic discharge occurs, it has ability to bear greater amounts of electric current. Additionally, the width of the P type diffusion region 110 can't be too narrow as to prevent a strong point electric field. In other words, the N type ring diffusion region 108 surrounds the perimeter of the P type diffusion region 110 such that a large electric current from the drain is not directed into the source (P type ring region 102). In this way, the transistor layout method according to the present invention possesses two advantages over the above-mentioned prior arts without incurring any of its shortcomings.

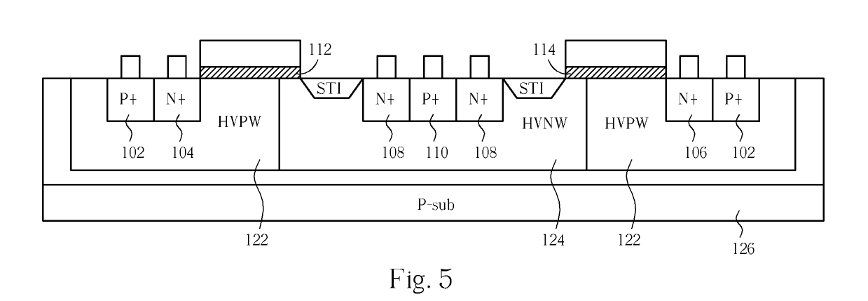

To further elaborate on the structure of the NSCR transistor 100, please refer to FIG. 5. FIG. 5 is a cross-section view of the NSCR transistor 100 shown in FIG. 4. As shown in the diagram, the main body of the NSCR transistor 100 is a P type semiconductor substrate 126 for increasing drift resistance of the NSCR transistor 100. A high Voltage N well (HVNW) covers the N type ring diffusion region 108 and the P type diffusion region 110. A high Voltage P well (HVPW) covers the P type ring region 102 and the rectangular N type diffusion regions 104, 106. Because dopant concentrations of the N and P wells are lower than that of the N and P type diffusion regions, it has a higher resistivity and can bear current resulting from a higher voltage.

Please note that the above-mentioned embodiment provides a general layout of an NSCR transistor for exemplary purposes. Permutations and alternate physical or structural arrangements, while still obeying the teachings described above, are still covered within the scope of the present invention. One skilled in this art can possibly provide slight modification to the above-mentioned NSCR transistor to provide an alternate structure and layout method of the PSCR transistor or other SCR transistor. However, such cosmetic structural changes would still follow the teachings of the present invention and therefore impinge on its area of limitation. The layout method described above is not solely limited to the above-mentioned manufacturing process, as other high voltage or logic manufactures my find it suitable for use.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A layout method for a transistor with increased ESD robustness, comprising:
defining a ring region of a first conductive type on a semiconductor substrate of the first conductive type;
defining a first rectangular diffusion region of a second conductive type within one side of the ring region of the first conductive type;
defining a second rectangular diffusion region of the second conductive type within another side of the ring region of the first conductive type, the first and second rectangular diffusion regions of the second conductive type being isolated from each other;
defining a ring diffusion region of the second conductive type between the first and second rectangular diffusion regions of the second conductive type;
defining a first diffusion region of the first conductive type on an inner side of the ring diffusion region of the second conductive type;
defining a first gate electrode between the first rectangular diffusion region of the second conductive type and the ring diffusion region of the second conductive region; and
defining a second gate electrode between the second rectangular diffusion region of the second conductive type and the ring diffusion region of the second conductive type;
wherein the ring diffusion region of the second conductive type and the diffusion region of the first conductive region correspond to a drain of the transistor, and the first and second rectangular diffusion regions of the second conductive type and the ring region of the first conductive type correspond to a source of the transistor.

2. The layout method of claim 1, wherein the diffusion region of the first conductive type is rectangular, and the layout method further comprises:
spacing a distance between the diffusion region of the first conductive type and the ring region of the first conductive type to be greater than a predetermined length.

3. The method of claim 1, further comprising:
defining a well of the second conductive type among the ring diffusion region of the second conductive type, the diffusion region of the first conductive type, and the semiconductor substrate of the first conductive type;
defining a first well of the first conductive type among the first rectangular diffusion region of the second conductive type, the ring region of the first conductive type, and the semiconductor substrate of the first conductive type; and
defining a second well of the first conductive type among the second rectangular diffusion region of the second conductive type, the ring region of the first conductive type, and the semiconductor substrate of the first conductive type.

4. The layout method of claim 1, wherein the transistor is a silicon-controlled rectifier cell (SCR cell).

5. A transistor with increased ESD robustness, comprising:
a semiconductor substrate of a first conductive type;
a ring region of the first conductive type formed on the semiconductor substrate of the first conductive type;
a first rectangular diffusion region of a second conductive type formed within one side of the ring region of the first conductive type;
a second rectangular diffusion region of a second conductive type formed within another side of the ring region of the first conductive type, the first and second rectangular diffusion regions of the second conductive type being isolated from each other;
a ring diffusion region of the second conductive type formed between the first and second rectangular diffusion regions of the second conductive type;
a first diffusion region of the first conductive type formed within an inner side of the ring diffusion region of the second conductive type;
a first gate electrode formed between the first rectangular diffusion region of the second conductive type and the ring diffusion region of the second conductive region; and
a second gate electrode formed between the second rectangular diffusion region of the second conductive type and the ring diffusion region of the second conductive type;
wherein the ring diffusion region of the second conductive type and the diffusion region of the first conductive region correspond to a drain of the transistor, and the first and second rectangular diffusion regions of the second conductive type and the ring region of the first conductive type correspond to a source of the transistor.

6. The transistor of claim 5, wherein the diffusion region of the first conductive type is rectangular, and a distance between the diffusion region of the first conductive type and the ring region of the first conductive type is greater than a predetermined length.

7. The transistor of claim 5, further comprising:
a well of the second conductive type formed among the ring diffusion region of the second conductive type, the diffusion region of the first conductive type, and the semiconductor substrate of the first conductive type;
a first well of the first conductive type formed among the first rectangular diffusion region of the second conductive type, the ring region of the first conductive type, and the semiconductor substrate of the first conductive type; and
a second well of the first conductive type formed among the second rectangular diffusion region of the second conductive type, the ring region of the first conductive type, and the semiconductor substrate of the first conductive type.

8. The transistor of claim 5, being a silicon-controlled rectifier cell (SCR cell).
